(19) United States
(12) Patent Application Publication
(10) Pub. No.: US 2009/0261830 A1
(43) Pub. Date: Oct. 22, 2009

(54) MAGNETIC RESONANCE IMAGING SCANNER

(75) Inventors: Nicholas Mann, Compton (GB); Stephen Paul Trowell, Alvingham (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney (GB)

(21) Appl. No.: 12/424,264

(22) Filed: Apr. 15, 2009

(30) Foreign Application Priority Data
Apr. 16, 2008 (GB) 0806903.1

(51) Int. Cl. G01R 33/31; F17C 3/02

(52) U.S. Cl. 324/318; 62/51.1

(57) ABSTRACT

A processor is provided in a MRI scanner which senses pressure within a cryogen vessel and the ambient environmental pressure outside of the scanner. It controls a pressure controller means in the cryogen to in turn control the pressure to ensure that it is set to provide as large a buffer as possible before a pressure relief valve is opened. This ensures that cryogen is not lost unnecessarily.

This invention relates to a Magnetic Resonance Imaging scanner and in particular to a controller for such a scanner which controls the pressure of a cryogen vessel held within the scanner.

Magnetic Resonance Imaging (MRI) scanners utilise large superconducting magnets which require cooling to liquid helium temperatures for successful operation. A containment structure is provided to enclose the magnets and to hold a large volume of the liquid helium to provide the cooling. Liquid helium is very expensive and thus the structure is designed to minimise its loss through heating from the environment. A multilayer structure is provided which is designed to minimise heat passing into the helium by conduction, convection and radiation.

The structure comprises a helium vessel which is innermost, a radiation shield spaced apart from the helium vessel, a number of layers of aluminised Mylar (RTM) polyester foil and insulation mesh, and then an outer vessel. This structure is evacuated during manufacture to minimise heat transfer from the outer vessel by convection and conduction. The radiation shield is formed of a high-grade aluminium to provide a highly reflective surface to minimise radiation of heat into the inner helium vessel.

Many current magnets use a refrigeration system that is capable of providing a small cooling capacity at liquid helium temperature. This results in a system that under normal conditions “re-condenses” and does not boil off any helium. The generation of an MRI image requires the application of a pulsed magnetic field (typically generated by a “gradient coil”). This generates eddy-currents in the helium vessel which result in an additional heat load. In typical 1.5 Tesla field strength magnets it is possible by proper design to avoid loss of helium under most imaging situations. However, the heating effect increases strongly with field strength and in for example 3.0 Tesla magnets it is difficult to avoid helium loss under all imaging conditions, especially those involving “aggressive” gradient pulse sequences.

In a re-condensing magnet the excess cooling capacity normally present may result in a low (“negative”) pressure being generated in the helium vessel. However, it is desirable to ensure that there is a positive pressure within the helium vessel at all times. The reason for this is that if the helium vessel experiences a negative pressure it may draw in atmospheric air. At liquid helium temperature the water vapour, nitrogen and other gases contained in the air will freeze out in the helium vessel leading in some cases to the formation of ice plugs. The ice plugs may cause the gas vent paths and excess pressure relief valves to be blocked. This can lead to highly undesirable safety consequences, with the risk of an excessive pressure build-up in the helium vessel leading to a catastrophic failure. It is thus normal practice to include safety devices to avoid the formation of ice plugs by maintaining a slightly positive pressure in the vessel at all times. To ensure safety, this pressure must be set above the highest atmospheric pressure that might be experienced at any time at any location around the world.

The temperature of the liquid helium increases with pressure. Hence, in order to maintain the low temperature required for the superconducting magnet, the helium vessel pressure cannot be allowed to rise too far (an excess pressure may result in an operating temperature above the normal temperature, which risks magnet “quench”, resulting in magnet down time and major loss of helium). This is typically achieved by an excess pressure valve which opens to allow helium to vent to atmosphere. The venting of the helium may be visible to the operator of the scanner and they, being conscious of the cost implications, may become dissatisfied with its performance.

To avoid the loss of helium during aggressive scans in particular it is desirable to ensure as wide a range as possible between the normal operating pressure (controlled by a pressure control means) and the limit at which the excess pressure valve opens. To ensure a safe positive pressure is always maintained, even under extreme (high) ambient pressure, this results in a narrow operating pressure range before helium venting starts. However, for the majority of systems, for most of the time this results in unnecessary risk of helium loss.

In one current design, operating pressure and vent pressure are controlled to fixed, absolute (i.e. independent of atmospheric pressure variation) values. This typically results in an operating pressure range before venting starts of less than 1 psi (6894.76 Pa), and the risk of negative pressure under extreme high ambient pressure.

In another current design, operating pressure and vent pressure are both controlled to fixed pressure differences relative to atmospheric pressure. This results in a fixed and relatively small operating range, and a magnet operating pressure then may become too high under high ambient pressure conditions, leading to increased risk of quench.

To avoid the loss of helium during aggressive scans in particular it is desirable to ensure as wide a range as possible between the normal, slightly positive, operating pressure and the limit at which the excess pressure valve opens. The present invention arose in an attempt to alleviate these problems. According to the invention there is provided a cryogen vessel containing, in use, a liquid cryogen, a pressure relief valve in the cryogen vessel wall responsive to the pressure therein to vent pressure out of the cryogen vessel when the valve opening pressure is exceeded, said valve opening pressure being independent of an environmental pressure, and means to control the pressure in the cryogen vessel to maintain a substantially constant positive pressure differential relative to an environmental pressure as the environmental pressure varies. By this means the excess pressure may always be maintained but in a way that ensures the operating buffer is the maximum possible, and consequently the risk of helium (or other cryogen) venting is minimised.

When it is also appreciated that the environmental pressure varies with the prevailing weather systems as well as altitude, it will be appreciated that significant operating efficiencies will be achieved.

A specific embodiment of the invention will now be described with reference to the drawing in which:

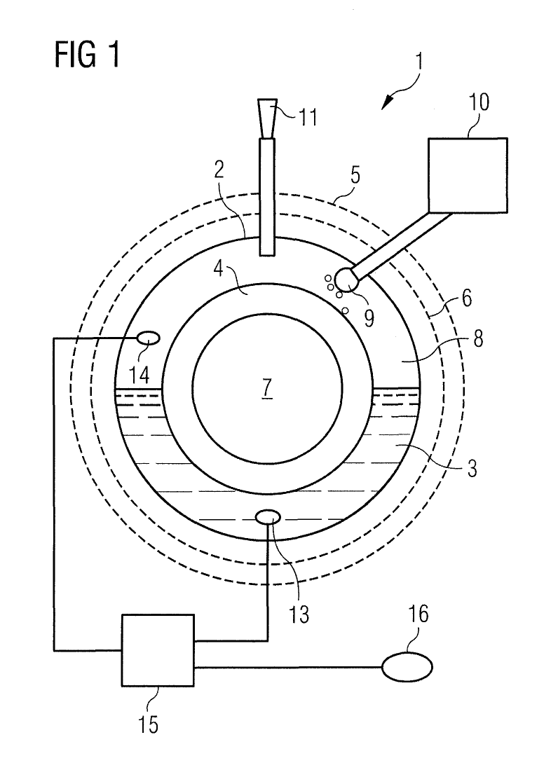

FIG. 1 shows a MRI scanner in accordance with the invention; and

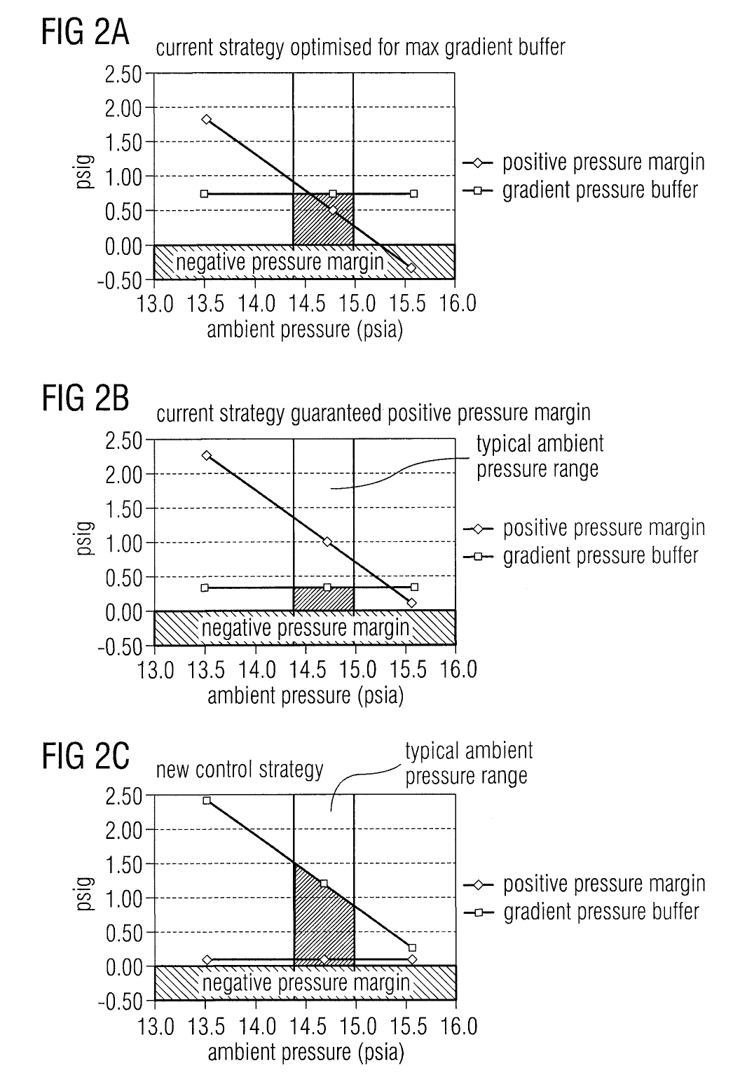

FIG. 2 is an explanatory diagram showing the operation of prior art scanners and a scanner in accordance with the invention.

As is shown in FIG. 1, a Magnetic Resonance Imaging scanner 1 comprises a cryogen vessel 2 containing liquid helium 3 located about superconducting magnets 4. The cryogen vessel 2 is located within an outer containment vessel 5 shown in broken outline and in spaced apart relationship to a radiation shield 6 also shown in broken outline.

The scanner is shown end-on and the various vessels are co-axial and formed as cylinders. In use a patient is passed though the annular core 7 to produce the scans in a manner well known to those skilled in the art.

The helium 3 cools the superconducting magnets 4 in order that they retain their properties of superconductivity. The helium vapour 8 above the liquid is cooled and condensed by a cooling head 9 connected to a refrigeration unit 10. A pressure relief valve 11 is ported into the helium vessel and opens at a pressure of 16 psi absolute (110316 Pa) to avoid an excessive pressure building up in the helium vessel 2. A pressure control means 13 is provided within the liquid helium for increasing the pressure to ensure a positive pressure is maintained within the helium vessel 2. A pressure sensor 14 is connected to the pressure vessel to sense the absolute pressure (The sensor may be mounted outside the vessel and connected by a pipe or located within the pressure vessel). This provides an output to a processor 15 which drives the pressure control means 13. A further pressure sensor 16 outside the helium vessel and the scanner itself senses the ambient environment pressure and provides an output representative thereof to the processor 15. Alternatively, ambient pressure and the pressure difference between the helium vessel and atmosphere may be measured, resulting in potentially lower cost and more reliable sensors.

The processor 15 may be a computer programmed to provide the required control functionality. It compares the ambient environmental pressure sensed by the sensor 16 with that present in the helium vessel 2 and sensed by the sensor 14. It then controls the pressure control means 13 to ensure that the pressure in the pressure vessel 2 is maintained above the ambient pressure by a small amount, for example 0.1 psi (689.476 Pa).

Thus as the ambient pressure varies the pressure control means 13 is controlled to vary the pressure in the helium in the vessel 2. This ensures that the buffer between the opening pressure of the valve 11 and the operating pressure is maintained to as large a value as possible. This avoids helium being lost and ensures that the scanner is operated as maximum efficiency no matter what type of scan is undertaken and whatever the current ambient environmental conditions.

The pressure control means 13 may introduce extra cryogen into the vessel to increase the pressure or other means to create a variation in the pressure. Alternatively, the processor can provide an output that interacts with the refrigerator control system to reduce its power and raise the temperature and hence pressure.

FIGS. 2a to 2c show the manner in which the invention increases the buffer. FIG. 2a illustrates a typical prior art strategy with the normal operating pressure set to 15.3 psia (105490 Pa) and the vent pressure set to 16.0 psia (110316 Pa). The gradient pressure buffer remains constant at 0.7 psi (4826 Pa). However, the positive pressure margin drops as the ambient pressure rises. This results in a negative pressure margin at high ambient pressures with the possibility of air ingress and consequential ice formation.

In FIG. 2b, the operating pressure margin is increased to ensure that at higher ambient pressures the pressure margin is always positive and the line does not cross into the negative pressure margin. To do this the normal operating pressure is raised to 15.7 psia (108248 Pa). A safe positive pressure margin is now maintained up to the higher ambient pressures but the gradient pressure buffer is greatly reduced to about 0.3 psi (2068 Pa).

FIG. 2c shows the control strategy of the described embodiment of the invention. The normal operating pressure is set and maintained at 0.1 psi (689.476 Pa) above the current ambient pressure and hence is always maintained at a safe operating pressure. The vent pressure remains at 16.0 psi (110316 Pa) and thus the gradient pressure buffer drops as the ambient pressure rises. However, the shaded area shows that the gradient pressure buffer is substantially larger within the typical ambient pressure range by using the invention.

1. A cryogen vessel containing, in use, a liquid cryogen, a pressure relief valve in the cryogen vessel wall responsive to the pressure therein to vent pressure out of the cryogen vessel when the valve opening pressure is exceeded, said valve opening pressure being independent of an environmental pressure, and means to control the pressure in the cryogen vessel to maintain a substantially constant positive pressure differential relative to an environmental pressure as the environmental pressure varies.

2. A cryogen vessel as claimed in claim 1, further comprising a sensor for sensing the ambient environmental pressure and providing an output representative thereof to the means to control the pressure in the cryogen vessel.

3. (canceled)

4. An MRI scanner comprising a superconducting magnet housed within a cryogen vessel according to claim 1.
